(19) United States
(12) Patent Application Publication
(10) Pub. No.: US 2016/0178289 A1
(43) Pub. Date: Jun. 23, 2016

(54) KINETIC HEAT-SINK WITH INTERDIGITATED HEAT-TRANSFER FINS

(71) Applicant: COOLCHIP TECHNOLOGIES, INC., Somerville, MA (US)

(72) Inventors: Lino A. Gonzalez, Somerville, MA (US); Steven J. Stoddard, Boston, MA (US)

(73) Assignee: COOLCHIP TECHNOLOGIES, INC., Somerville, MA (US)

(21) Appl. No.: 14/910,430

(22) PCT Filed: Aug. 21, 2014
(86) PCT No.: PCT/US2014/051987

§ 371 Date: Feb. 5, 2016

Related U.S. Application Data
(60) Provisional application No. 61/868,362, filed on Aug. 21, 2013.

(51) Int. Cl. F28F 5/04; H01L 23/373; H01L 23/467; H01L 23/367; F28F 13/12; F28F 13/14

(52) U.S. Cl. CPC F28F 5/04; F28F 13/12; F28F 13/14; H01L 23/467; H01L 23/3672; H01L 23/3675; H01L 23/3736

(57) ABSTRACT

A kinetic heat sink has a stationary portion with a first heat-conducting surface and a second heat-conducting surface to conduct heat therebetween. To cool heat generating devices devices, the stationary portion is mountable to a heat-generating component and has a first plurality of fins extending therefrom. The kinetic heat sink also has a rotating structure rotatably coupled with the stationary portion. The rotating structure is configured to transfer heat received from the second heat-conducting surface to a thermal reservoir in thermal communication with the rotating structure. The rotating structure has a movable heat-extraction surface with a second plurality of fins extending toward the first plurality of fins. At least a portion of the first plurality of fins preferably are interdigitated with at least a portion of the second plurality of fins.

### PRIORITY

This patent application claims priority from provisional U.S. Patent Application No. 61/868,362, filed Aug. 21, 2013, entitled, “KINETIC HEAT-SINK WITH CONCENTRIC INTERDIGITATED HEAT-TRANSFER FINS,” and naming Lino A. Gonzalez and Steven J. Stoddard as inventors, the disclosure of which is incorporated herein, in its entirety, by reference.

### TECHNICAL FIELD

The present invention generally relates to rotating heat-extraction and dissipation devices and, more particularly, the present invention relates to kinetic heat sinks for use with electronic components.

### BACKGROUND ART

During operation, electric circuits and devices generate wasted heat. To operate properly, the temperature of the electric circuits and devices typically has to be within certain limits. To that end, the temperature of an electric device often is regulated using a heat sink physically mounted near or on the electric device.

One relatively new type of heat sink assembly, known as a “kinetic heat sink” (KHS), has a thermal mass with integrated fluid-directing structures that rotate with respect to a stationary base mounted on or near the heated electronic device. Kinetic heat sinks have the potential to provide better cooling than stationary heat sinks.

### SUMMARY OF ILLUSTRATIVE EMBODIMENTS

To the knowledge of the inventors, various topologies of the stationary component and rotating portion of a kinetic heat sink have been developed. The inventors recognized, however, that the interface between such topologies often requires surface features at precise tolerances (often in the micrometer scale) to obtain the desired heat-extraction and dissipation performance. Such requirements often require precise manufacturing techniques that are not adaptable for standard manufacturing equipment. The inventors nevertheless discovered a technology that permits increased tolerance limits that facilitate use with standard manufacturing equipment.

In accordance with illustrative embodiments, a kinetic heat sink has a stationary portion with a first heat-conducting surface and a second heat-conducting surface to conduct heat therebetween. To cool heat-generating devices, the stationary portion is mountable to a heat-generating component and has a first plurality of fins extending therefrom. The kinetic heat sink also has a rotating structure rotatably coupled with the stationary portion. The rotating structure is configured to transfer heat received from the second heat-conducting surface to a thermal reservoir in thermal communication with the rotating structure. The rotating structure has a movable heat-extraction surface with a second plurality of fins extending toward the first plurality of fins. At least a portion of the first plurality of fins preferably are interdigitated with at least a portion of the second plurality of fins. The stationary base and/or rotating structure may include structural features to improve the heat transferring characteristics of the radial gaps. The structures may, for example, disrupt the formation of undesired fully developed flow that would form due to the rotating structure's steady rotation or form a localized secondary flow at the operating speed of the device to do the same. The features may be protrusions, recesses, gaps, or combination thereof situated within the walls, ceiling, or floor of the channels formed by the interdigitated fins.

In accordance with another embodiment of the invention, a method of dissipating heat from an electronic device provides a stationary structure having a first and second heat-conducting surface. The stationary structure is thermally coupled to the electronic device at the first heat-conducting surface to receive heat from the electronic device, and conducts the received heat from the first heat-conducting surface to the second heat-conducting surface. The second heat conducting surface includes a first plurality of fins. The method also rotates a rotating structure having a heat-extraction surface facing the second heat-conducting surface. The heat-extraction surface has a second plurality of fins interdigitated with the first plurality of fins. The act of rotating at least in part substantially transfers heat from the second heat-conducting surface to a thermal reservoir communicating with the rotating structure.

### BRIEF DESCRIPTION OF THE DRAWINGS

The foregoing features of embodiments will be more readily understood by references to the following detailed description, taken with reference to the accompanying drawings, in which:

FIG. 1 schematically shows a cross-sectional view of a kinetic heat sink with interdigitated heat-transfer fins according to an illustrative embodiment of the invention.

FIG. 2 schematically shows plan views of interdigitated fins of a kinetic heat sink according to an illustrative embodiment of the invention.

FIG. 3 schematically illustrates the operation of the kinetic heat sink to dissipate heat according to an illustrative embodiment of the invention.

FIG. 4 schematically shows geometric features of the interdigitated fins.

FIG. 5 illustrates a prior art kinetic heat sink.

FIGS. 6A-6G illustratively show cross-sectional views of kinetic heat sinks with interdigitated fins according to various alternate embodiments of the invention.

FIG. 7A illustratively shows a cross-sectional view of a kinetic heat sink with interdigitated fins with circulation ports according to an illustrative embodiment of the invention.

FIG. 7B illustratively shows the rotating structure of the kinetic heat sink with straight fins according to an illustrative embodiment of the invention.

FIGS. 8A-8D illustratively show portions of the kinetic heat sink of FIG. 7B with various embodiments of interdigitated fins and circulation ports.

FIG. 9A schematically shows a kinetic heat sink according to an alternative embodiment of the invention.

FIG. 9B schematically shows a portion of the kinetic heat sink of FIG. 9A with rounded circulation ports in the rotating structure.

FIG. 9C schematically shows a kinetic heat sink with stationary fins according to another illustrative embodiment of the invention.

FIG. 10A schematically shows a kinetic heat sink with interdigitated fins according to another embodiment of the invention.

FIG. 10B schematically shows the kinetic heat sink of FIG. 10A with an electric motor assembly.

FIG. 11A schematically shows a cross-sectional view of a kinetic heat sink with interdigitated fins according to an illustrative embodiment of the invention.

FIG. 11B schematically shows interdigitated fins with features to improve the heat transferring characteristics of the radial gaps according to an illustrative embodiment of the invention.

FIG. 11C schematically shows interdigitated fins with other features to improve the heat transferring characteristics of the radial gaps according to another illustrative embodiment of the invention.

FIG. 12 schematically shows exemplary fluid flow within the interdigitated fins according to an illustrative embodiment of the invention.

FIG. 13 shows a process of operating the kinetic heat sinks in accordance with illustrative embodiments of the invention.

### DETAILED DESCRIPTION OF SPECIFIC EMBODIMENTS

In illustrative embodiments, a kinetic heat sink has interdigitated fins between its stationary and rotating components to produce radial heat transfer—in addition to, or instead of, axial heat transfer. The inventors were surprised to learn that such a kinetic heat sink did not require the precise and complex tolerances of prior art kinetic heat sinks that rely primarily on axial heat transfer. Specifically, although the interdigitated fins introduce more critical surfaces than a single axial surface, the interdigitated fins permit larger gaps. Favorably, these larger gaps are easier to control since, in general, radial run-out is more controllable than axial run-out. Accordingly, in many such embodiments, standard manufacturing equipment and techniques can produce more efficient kinetic heat sinks Additionally, with this innovation, the stationary and rotating portions may transfer waste heat more effectively without increasing the overall device footprint. Thus, a kinetic heat sink implementing illustrative embodiments often can dissipate more waste heat than a prior art heat kinetic heat sink having the same footprint.

Interdigitated fins also can form a labyrinth-type seal preventing dust from entering the regions between the stationary and rotating components. This is especially effective in protecting inner components (e.g., the motor or spindle) from dust contamination.

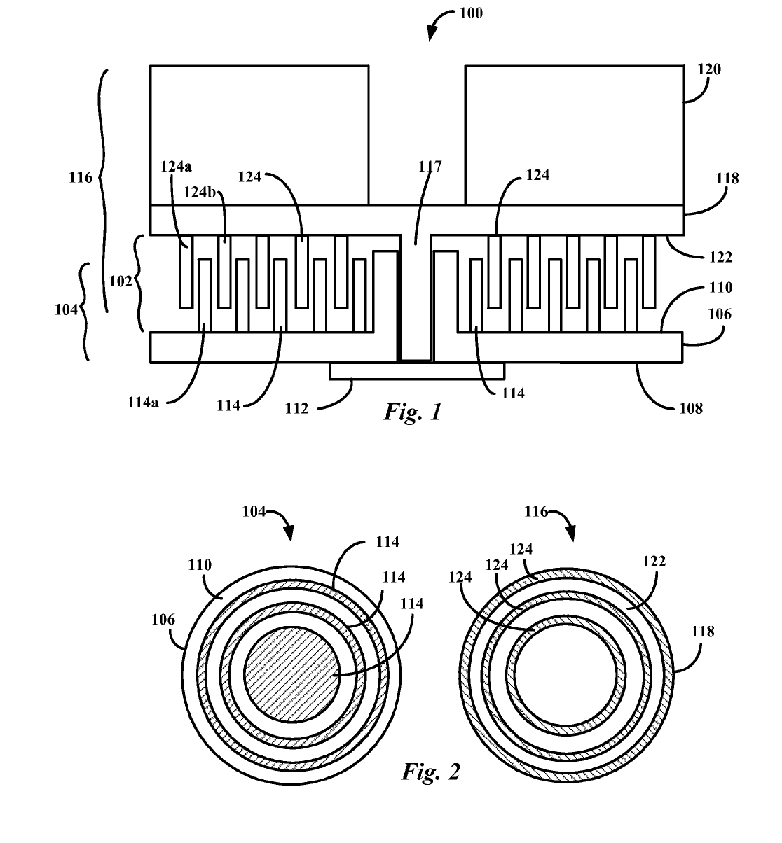

FIG. 1 schematically illustrates a kinetic heat sink 100 with interdigitated fins 102 according to illustrative embodiments of the invention. Specifically, the kinetic heat sink 100 includes a stationary portion 104 having a base structure 106 with a first heat-conducting surface 108 and a second heat-conducting surface 110. The first heat-conducting surface 108 is configured to fixably mount to a heat-generating component 112 (e.g., electric device, microprocessor, chip, etc.). The second heat-conducting surface 110 forms a set of stationary fins 114, which form a part of the interdigitated fins 102.

The kinetic heat sink 100 also includes a rotating structure 116 that rotatably couples with the stationary portion 104 via a shaft 117 to rotate substantially within a plane. The rotating structure 116 includes a rotating base 118 and fluid-directing structures 120 (e.g., additional fins or blades). The rotating base 118 has a heat-extracting surface 122 that forms a set of rotating fins 124, which forms the interdigitated fins 102 with the first set of fins 114. The stationary fins 114 and rotating fins 124 may be concentric with the axis of rotation of the rotating structure 116. Other embodiments do not require that the stationary fins 114 be concentric with the rotating fins 124. For simplicity purposes, however, much of this discussion relates to concentric fins although various principals can be applied to non-concentric fins. The stationary portion 104 and the rotating structure 116 may be made of the same or different thermal conducting material. For example, the structures 104 and 116 can be formed from copper, aluminum, silver, nickel, iron, zinc, and combinations thereof.

Accordingly, the interdigitated fins 102 are formed from overlapping stationary fins 114 and rotating fins 124, for example, in the manner shown in the figures. Stated another way, the fins 114, 124 are considered to be interdigitated because they longitudinally overlap each other, permitting them to non-negligibly transfer heat between their radially adjacent surfaces.

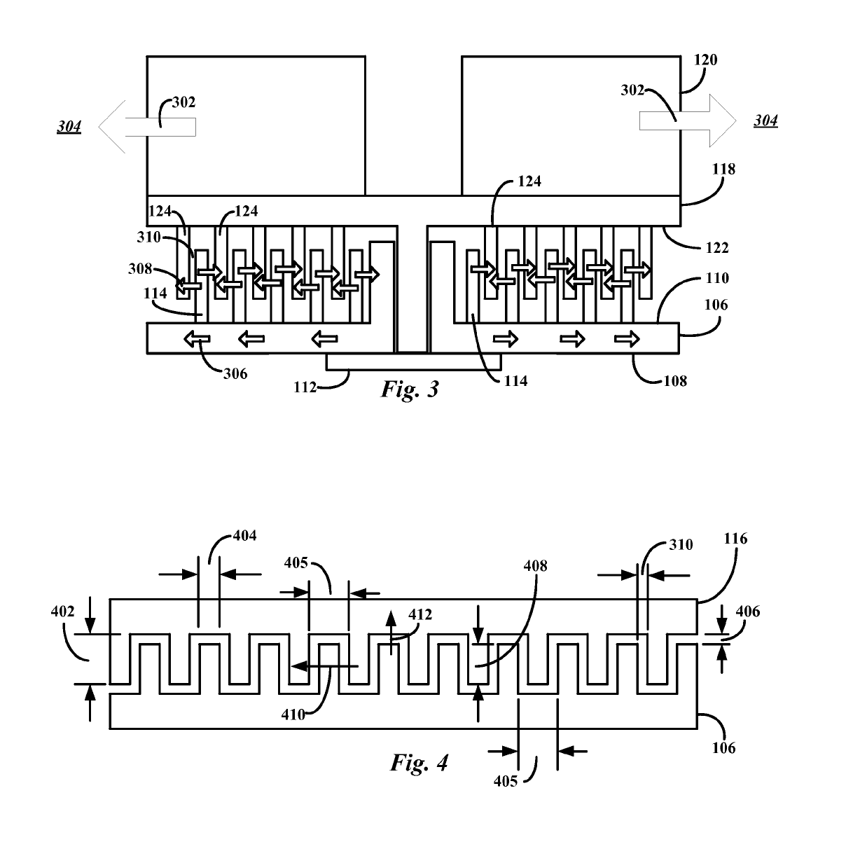

Concentrically interdigitated fins provide a buffer from misalignment during operations. A misalignment, for example, between the stationary portion 104 and the rotating structure 116, may result in varying radial gaps 310 (not shown—see FIG. 3) between their corresponding interdigitated fins 102. For example, a stationary fin 114a may be positioned closer to a first rotational fin 124a next to one of its faces, but farther away from a second rotational fin 124b next to the other of its faces. The offset consequently decreases the local thermal resistance with the first fin 124a, while producing a corresponding increase to the thermal resistance with the second fin 124b. The radial gaps 310 can be between about 10 and 100 microns, and more specifically between about 25 and 50 microns. In preferred embodiments, the radial gaps can be as large as between about 100 and 200 microns, and more preferably between about 125 and 150 microns.

FIG. 2 schematically shows plan views of concentric, interdigitated fins 102 of the kinetic heat sink 100 of FIG. 1. The set of stationary fins 114 concentrically extends from the second heat-conducting surface 110 of the base structure 106. In a corresponding manner, the set of rotating fins 124 concentrically extends from the heat-extracting surface 122 of the rotating base 118. Of course, to interdigitate, the radii of the set of stationary fins 114 differ from the radii of the set of rotating fins 124.

FIG. 3 schematically illustrates the operation of the kinetic heat sink 100 of FIG. 1. During operation, fluid-directing structures 120, among other things, dissipate heat 302 to the thermal reservoir 304 (e.g., the air around the kinetic heat sink 100) while heat is generated by the heat-generating component 112. To that end, heat from the heat-generating component 112 is spread (see arrows 306) across the base structure 106 to the concentric fins 114. Heat from the set of stationary fins 114 then is primarily transferred 308 across radial gaps 6 310 to the corresponding overlapping surfaces of neighboring rotating fins 124. The heat spreads from the set of rotating fins 124 to the other portions of the rotating structure 116, including the rotating base 118 and the fluid-directing structures 120, and thus is rejected to the thermal reservoir 304.

FIG. 4 schematically shows some geometric features of the interdigitated fins 102. In illustrative embodiments, the geometry of each fin 114 or 124 may be characterized as having a length L 402, a width W 404, and a distance D 405 to a neighboring fin. The interdigitated fins 102 also may be considered to form the radial gaps δ 310 (effectively forming channels) between each neighboring fin, an axial gap h 406 between the base structure 106 and the rotating structure 116, a height H 408 defining the overlapping portions of the first and second sets of fins 114, 124, and the number N representing the channels formed by the fins 102. Accordingly, heat from the heat-generating component 112 spreads across the base structure 106 to the first set of fins 114 of length L 402 and width W 404.

FIGS. 2 and 4 illustrate larger features and structures that may be manufactured using standard equipment and techniques.

FIG. 2 shows relevant portions of the rotating structure 116 and a stationary portion 104 of the kinetic heat sink 100 as separate, unassembled parts. The stationary fins 114 and the rotating fins 124 may be manufactured in the structure based on the width W 404 of the corresponding fins and the radial gaps 6 310 (see FIG. 4). The structures may be manufactured, for example, with a milling machine, a lathe, or drill. The machine may have a tool head of size of distance D 405 or smaller, which may equate to W+2δ. A vertical lathe, for example, may form a series of grooves, each 1.1 mm wide, with a spacing of 1 mm. The grooves correspond to the distance D 405 and the spacing corresponds to the width W 404 of the fins 114, 124. To that end, the tool bit may have a size up to 1.1 mm with tolerances of at least half of the radial gap 310. The fins 114, 124 may be manufactured with other width W 404 or distance D 405, such as between 1 and 3 mm. Of course, other standard manufacturing techniques, such as etching, stamping, casting, and forging may be employed to fabricate the device.

In other embodiments, the fins may be fabricated and attached to the base regions of the stationary portion 104 and the rotating structure 116 via, for example, soldering, brazing, welding, and adhering (such as with glue, cement, and adhesives).

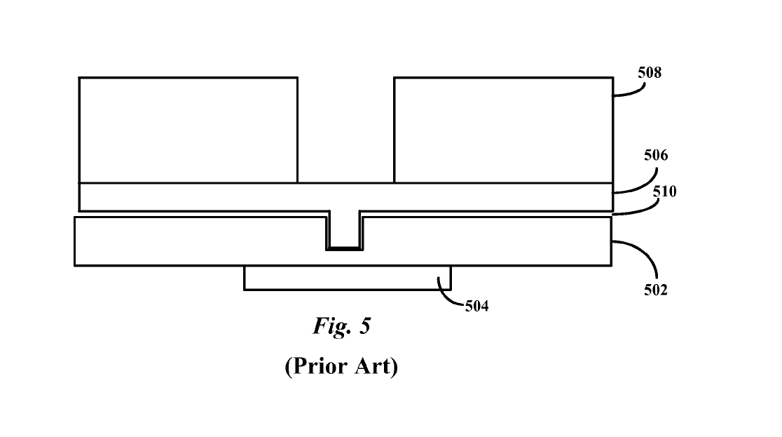

In contrast, kinetic heat sinks that have parallel or angled heat transfer surfaces are generally manufactured at dimensions defining the axial gap. FIG. 5 illustrates one such class of prior art kinetic heat sink known in the art. A stationary base structure 502 is mounted to a heat-generating component 504. A rotating structure 506 with an impeller 508 is coupled to the stationary base structure 502 to form parallel surfaces spanning a substantial footprint of the device across an axial gap 510. Manufacturing parallel surfaces with such precision typically increases the cost of this class of kinetic heat sinks compared to similarly size thermal solutions.

Referring back to FIG. 4, various embodiments may have an increased effective heat-transfer conductance (Q/ΔT) _{increase} that is proportional to the surface area, and inversely proportional to gap thickness between the surfaces. When compared to the heat transfer conductance of parallel or angled surfaces, the increase may be expressed as

$${( Q / Δ T )}_{increase} = \frac{H}{W} .$$

For example, a kinetic heat sink having two surfaces with concentric fins that (i) are interdigitated such that

$$\frac{H}{W} = 3$$

and (ii) radial gaps δ 310=45 microns may have a thermal conductance of ˜10 W/C. To have a similar thermal conductance, a kinetic heat sink with parallel surfaces may have a gap 510 spaced 15 microns axially apart, which is three times smaller than the radial gaps δ (310). Of course, other thermal conductances may be produced.

To that end, the stationary fins 114 and rotating fins 124 may have a height 402 to width W 404 ratio (H/W) of at least two, more preferably in the range of at least three, and even more preferably, in the range of three and six. In other embodiments, stationary fins 114 and rotating fins 124 may have a length L 408 to distance D 405 ratio (L/D) of at least two, more preferably in the range of at least three, and even more preferably, in the range of three and six. In yet other preferred embodiments, the overlapping surface area between the fins 114,124 in the radial direction 410 is at least two times greater than in the axial direction 412, more preferably in the range of at least three, and even more preferably, in the range of three and six.

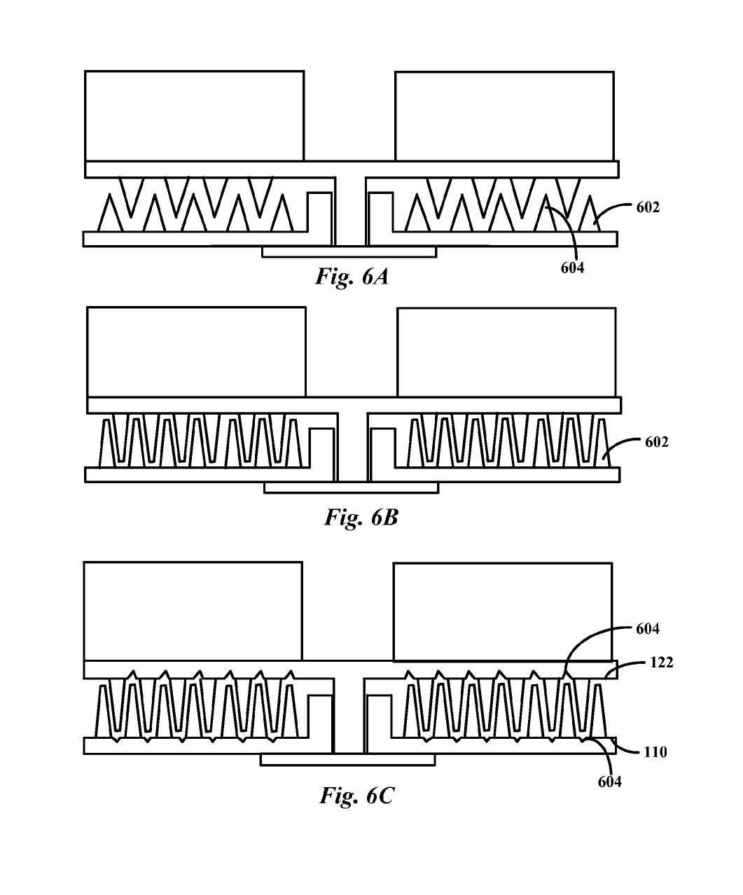

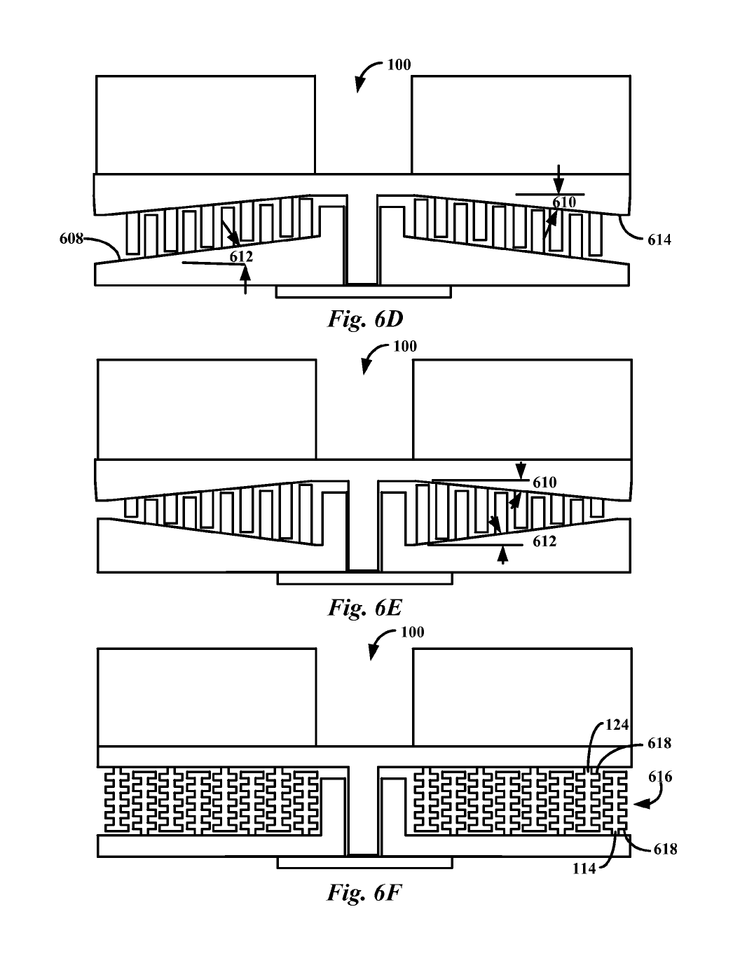

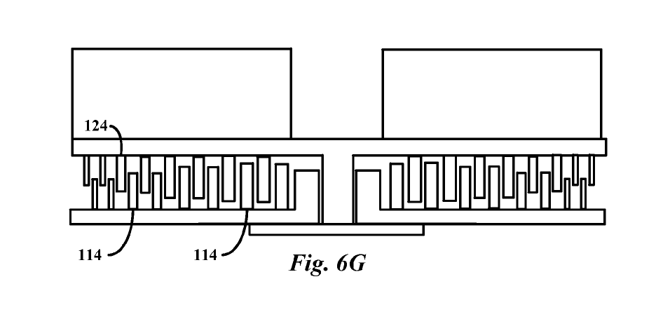

The interdigitated fins 102 may be adapted with various geometries, including differing height, thickness, and tapering angle. FIGS. 6A-6G illustratively show kinetic heat sinks 100 with concentrically interdigitated fins 102 according to various embodiments.

In FIG. 6A, the kinetic heat sink 100 includes concentrically interdigitated tapered fins 602 having a triangular cross-sectional area. The tapered fins 602 may have an inside angle 604 between about 10 and 60 degrees. The tapered fins 602 allows for higher heat transfer density due to having more effective heat transfer area.

In FIG. 6B, the concentrically interdigitated tapered fins 602 have a trapezoidal cross-sectional area.

In FIG. 6C, the second heat-conducting surface 110 or a heat-extracting surface 122 may include surface features 604, such as grooves to flow fluid to more readily flow between different stages of the interdigitated fins from the inner radial portion to the outer radial portion of the device.

The kinetic heat sink 100 may be configured with radial and axial gaps (310, 406) that vary along the radial direction 410. The variation may compensate for larger run-out and higher shearing losses at the outer radial location. In one embodiment, for example, the radial gaps δ 310 and axial gaps h 406 may increase from the inner radial location to the outer radial location.

In FIG. 6D, the stationary portion 104 has a tapered surface 608 having an angle 612, and the rotating structure 116 has a tapered surface 614 having an angle 610. The angles 610, 612 may be between about 1 and 30 degrees and may be the same. The concentrically interdigitated fins 102 extend from tapered surfaces 608, 614.

In FIG. 6E, a kinetic heat sink 100 with concentrically interdigitated fins extends from opposing or diverging tapered surfaces 608, 614. As a result, length L 402 of the concentrically interdigitated fins 102 may vary along the radial direction 410 resulting in the radial gaps 310 in the inner region to be greater than the outer region of the device.

In FIG. 6F, the concentrically interdigitated fins 102 may have complex shapes 616 that have greater effective heat transfer surface areas. For example, each interdigitated fin 102 may include a set of secondary fins 618 extending therefrom. The secondary fins 618 may vary the width W 404 of each interdigitated fin 102 along the length L 402. Some embodiments interdigitate portions of the secondary fins 618.

In FIG. 6G, the fins 114, 124 may have varying width W 404 or varying height H 402. As shown, the height H 402 and width W 404 between the rotating fins 124 differ as well as between the stationary fins 114. Additionally, the spacing between the fins may vary among different radial locations. For example, the radial gap δ 310 at a radial position near the center of the device may be smaller compared to the radial gap δ 310 at a radial position near the perimeter. The change in radial gaps δ 310 among different radial location may be based on a linear function, a polynomial function, or an exponential function.

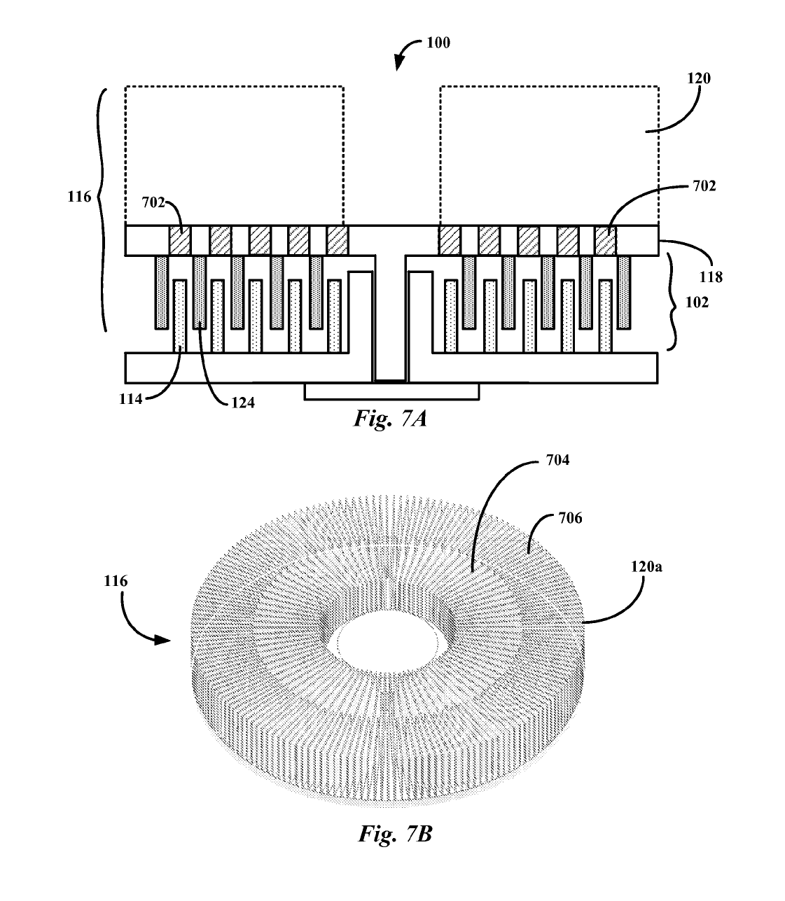

FIG. 7A illustratively shows another embodiment of the kinetic heat sink 100 with concentrically interdigitated fins 102 and circulation ports 702. The ports 702 permit fluid flow from the fluid-directing structures 120 into the interdigitated fins 102, and vice versa. The circulation ports 702 may be located in the rotating structure 116, specifically at the rotating base 118 between the fluid-directing structures 120. The circulation ports 702 may be circular, arc-shaped, or angled.

FIG. 7B illustratively shows the fluid-directing structure 120 of the kinetic heat sink according to illustrative embodiments. In this example, the rotating structure 116 includes a set of one hundred eighty fins including ninety long straight fins 704 and ninety short straight fins 706 interposed among each other as part of the fluid-directing structures 120. The set of long fins 704 may span a substantial portion of the rotating base 118, for example, over fifty percent of the diameter. In one embodiment, the rotating structure 116, for example, has an outer diameter of 8.89 cm and a height of 1.27 cm to provide a surface area of 1050 cm². When compared to a kinetic heat sink of comparable footprint having only long fins (e.g., having a surface area of 59 cm²), the surface area of the rotating structure 116 is nearly 22 percent greater. Here, the rotating structure 116 includes the rotating interdigitated fins 124, though not shown. Of course, other straight fin and impeller configurations may be employed.

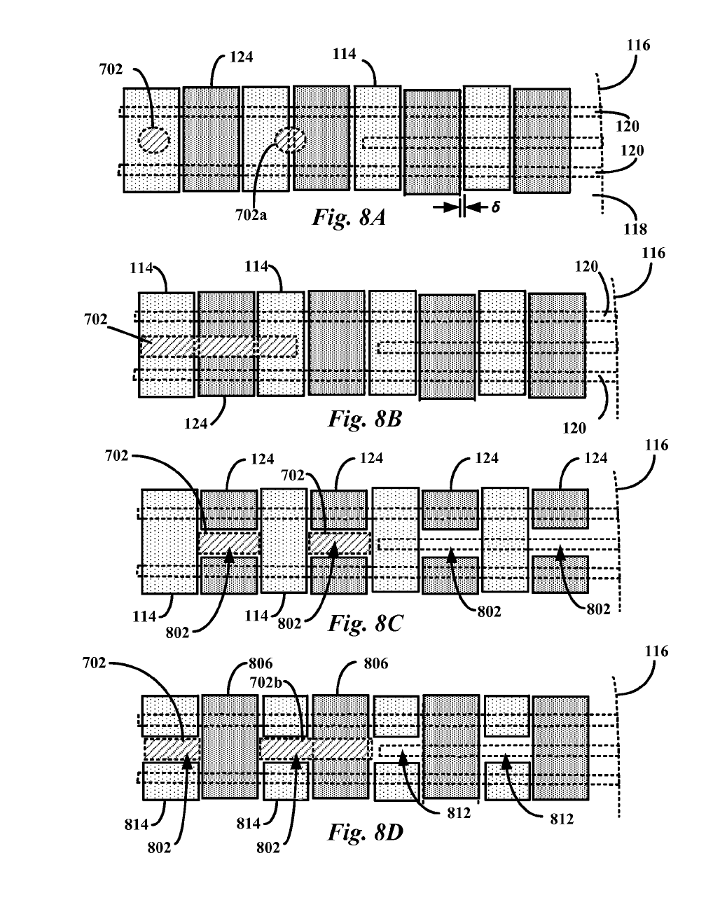

FIGS. 8A-8D illustratively show portions of the kinetic heat sink 100 of FIG. 7B with various embodiments of interdigitated fins 102 and circulation ports 702. Specifically, FIG. 8A shows a top view of a portion of the rotating structure 116 with rounded circulation ports 702. The circulation ports 702 are shown in relation to the interdigitated fins 102. The circulation ports 702 are disposed in the rotating base 118 between the fluid-directing structures 120. The circulation ports 702 may be disposed over one set of fins, such as the rotating fins 124 and the stationary fins 114. The circulation ports 702a may be disposed over the radial gaps δ 310 between the stationary and rotating interdigitated fins 114, 124.

FIGS. 8B shows a top view of a portion of the rotating structure 116 with circulation ports 702 that extend across a pair of interdigitated fins 102. The circulation ports 702 are shown as an elongated strip disposed between the fluid-directing structures 120. The circulation ports 702 may be located at different radial location. Of course, the circulation ports 702 may have other lengths extending radially in the rotating structure 116.

FIG. 8C schematically shows the rotating structure 116 of FIG. 8B with discontinuity 802 in the rotating fins 124. The circulation ports 702 may be disposed at the discontinuity 802. The discontinuity 802 may be located along the same radial direction (as shown) or along different radial location. The width of the discontinuity 802 may also vary among different discontinuities 802. The rotating fins 124 may also be tapered or rounded at the discontinuity 802.

FIG. 8D schematically shows the rotating structure 116 of FIG. 8B with discontinuity 802 in the stationary fins 114. The circulation ports 702 may be disposed at the discontinuity 802. Another set of circulation ports 702b is disposed at the discontinuity 802 of the stationary fins 114 and the rotating fins 124. The discontinuity 802 may be located along the same radial direction (as shown) or along different radial location. The width of the discontinuity may also vary between different discontinuities. The stationary fins 114 may also be tapered or rounded at the discontinuity 802.

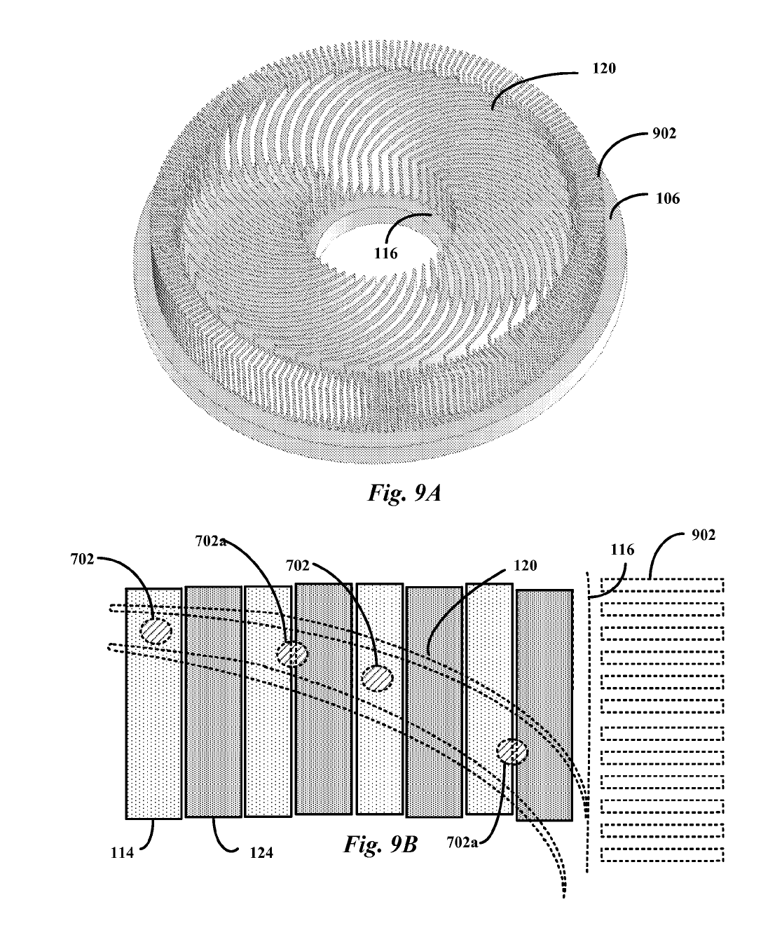

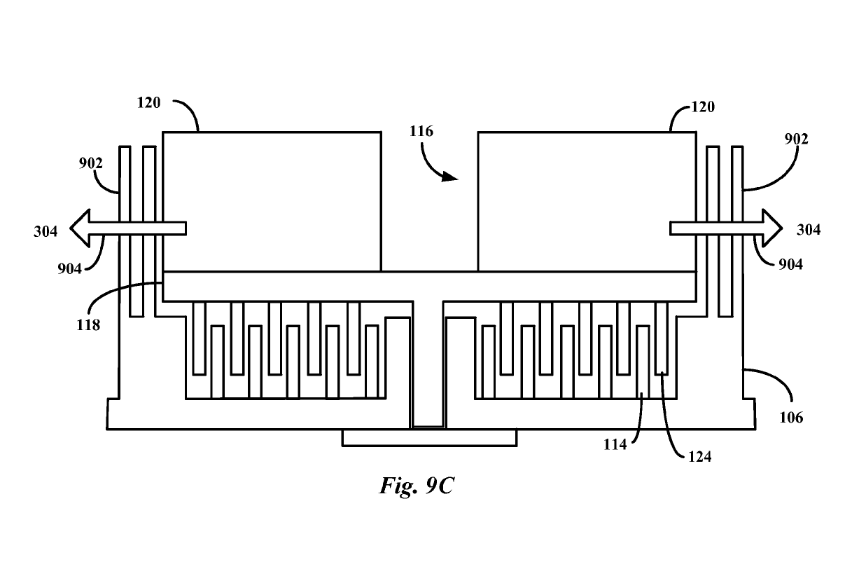

FIGS. 9A and 9C illustratively show a kinetic heat sink 100 with interdigitated fins 102 and secondary stationary fins 902 according to an embodiment of the invention. Examples of secondary stationary fins 902 are described in U.S. Provisional Application No. 61/816,450, titled “Kinetic Heat Sink With Stationary Fins,” filed Apr. 26, 2013, and International Patent Application Number PCT/US14/30162, filed Mar. 17, 2014, claiming priority to the immediately noted provisional patent application, both of which are incorporated by reference herein in their entireties. The secondary stationary fins 902 extend from the base structure 106 and provide additional surface area for heat rejection. The secondary stationary fins 902 are in the path 904 (see FIG. 9C) between the fluid-directing structures 120 and the surrounding thermal reservoir 304. In this embodiment, fluid-directing structures 120 include a set of forty-two curved rectangular fins that spans nearly 86% of the footprint of the kinetic heat sink 100. The set of secondary stationary fins 902 includes two hundred straight-radial fins that span nearly 12 percent of the footprint of the kinetic heat sink 100.

In an embodiment, the footprint of the kinetic heat sink may, for example, have a total outer diameter of 8.89 cm. The set of fluid-directing structures 120 has a radial length of 7.62 cm having a surface area of 43 cm². The addition of the set of secondary stationary fins 902 having a length of 1.016 cm, a cross-sectional area of 0.5 mm forming channels 0.5 mm wide may increase the surface area by 28 cm². Of course, other dimensions and fin numbers may be employed.

FIG. 9B illustratively shows a top view of a portion of the kinetic heat sink 100 of FIG. 9A with rounded circulation ports 702, 702a in the rotating structure 116. The circulation ports 702, 702a are shown in relation to the interdigitated fins 102.

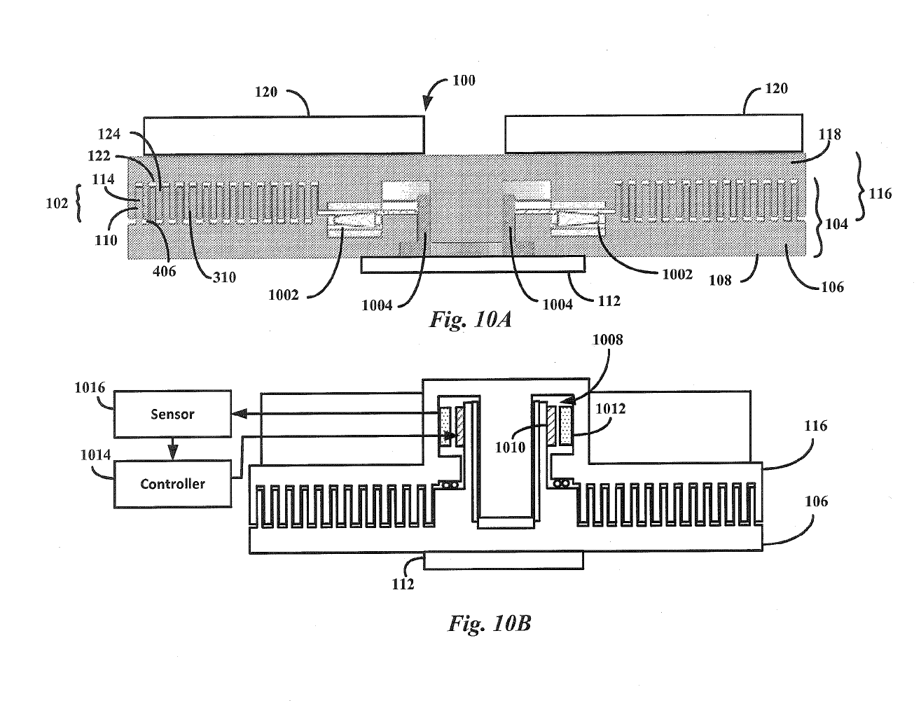

FIG. 10A schematically illustrates a kinetic heat sink 100 with interdigitated fins 102 according to another embodiment of the invention. Specifically, the kinetic heat sink 100 includes an axial bearing 1002 between the rotating structure 116 and the stationary portion 104. Various types of bearings may be employed, including roller thrust bearings, bushing, rolling element bearings, fluid bearings, and air bearings, among others. The axial bearing 1002 are adapted to maintain the axial gaps h 406 between the rotating structure 116 and the stationary portion 104. In alternate embodiments, the axial bearings 1002 may be in the outer radial portion of the kinetic heat sink 100.

The kinetic heat sink 100 may include a radial bearing 1004 between the rotating structure 116 and the stationary portion 104 to maintain the radial gaps δ 310 and align the two structures 104, 116. The rotating structure 116 may include a shaft portion 1006 configured to communicate with the radial bearing 1004. The shaft portion 1006 may be integrated as part of the rotating structure 116, while the radial bearing 1004 is attached to the stationary portion 104.

FIG. 10B shows another heat sink embodiment, having an electric motor assembly 1008. In this embodiment, the rotating structure 116 is rotatably coupled to the stationary portion 104 through the motor assembly 1008, which includes a motor-stationary component and a motor-rotating component. The motor-stationary component may include a stator 1010 (i.e., electrical windings and armature) and, optionally, a housing. The motor-rotating component may include a rotor shaft and components attached thereon, including, for example, permanent magnets 1012 (in some embodiments). The motor-stationary component, preferably, is fixably coupled to the stationary portion 104 and thus, may be considered part of the stationary member. The motor-rotating component may be fixably coupled or coupled via a gear to the rotating structure 116. The motor-stationary component and the motor-rotating component preferably are generally concentrically located between the rotating structure 116 and the stationary portion 104.

Any number of different motor configurations may be used. For example, the kinetic heat sink may include a controller 1014 to regulate the rotation speed of the rotating structure 116 by regulating the current or voltage provided to the electrical winding. In an illustrative embodiment, the electrical winding is part of the motor-stationary component. However, it should be apparent to those skilled in the art that various motor topologies may be employed, including designs having the electrical winding being part of the motor-rotating component. The controller 1014 may include a control circuit, a driver circuit, and corresponding signal processing circuitries. The controller 1014 may be mounted within or on the stationary portion 104. The control circuit may be configured to provide pulse-width modulation, frequency, phase, torque, and/or amplitude control.

The kinetic heat sink may also include a sensor 1016 to provide feedback signals for the controller 1014. The feedback signals may be based upon the speed or temperature. The speed may include the rotational speed of the rotating portion 116 and/or of the motor. The temperature may be of the heat-generating component 112, the stationary portion 104, the rotating structure 116, the radial gaps 310 and/or the motor 1008. Among other things, the sensor 1016 may be a capacitive-based sensor, a thermocouple, and/or an infrared detector and may output an electrical signal that is un-scaled or offset and merely have some correlation to the temperature value. It should be apparent to those skilled in the art that various controllers and control schemes may be utilized to regulate the heat dissipating apparatus based upon temperature, rotation speed, and clearance gap. It also should be apparent to those skilled in the art that a portion of the motor-stationary component (e.g., the electrical winding) may be placed in various locations that are concentric the axis of rotation.

For example, rather than the motor assembly 1008 being proximal to or near the axis of rotation, the motor-stationary component (having the electrical windings) may be located distally to the rotor axis. Similarly, it is contemplated that parts of the motor-stationary component (e.g., electrical winding) may be located on top of the rotating structure 116 or within the stationary portion 104.

Various direct-current and alternating—current based motor may be employed. Examples of direct-current (DC) based motors may include brushed DC motors, permanent-magnet electric motors, brushless DC motors, switched reluctance motors, coreless DC motors, universal motors. Examples of alternating-current (AC) based motors may include single-phase synchronous motors, poly-phase synchronous motors, AC induction motors, and stepper motors. The motor assembly may include an integrated motor controller, such as a servo motor. The motor may operate based upon pulse-width modulation scheme or direct current control.

The embodiment may employ conventional spindle motors (e.g., fluid dynamic spindle motors). Spindle motors, such as a fluid dynamic bearing spindle motor, are described in U.S. patent application Ser. No. 13/911,677, titled “Kinetic heat sink having controllable thermal gap,” filed Jun. 6, 2013, which is incorporated by reference herein in its entirety.

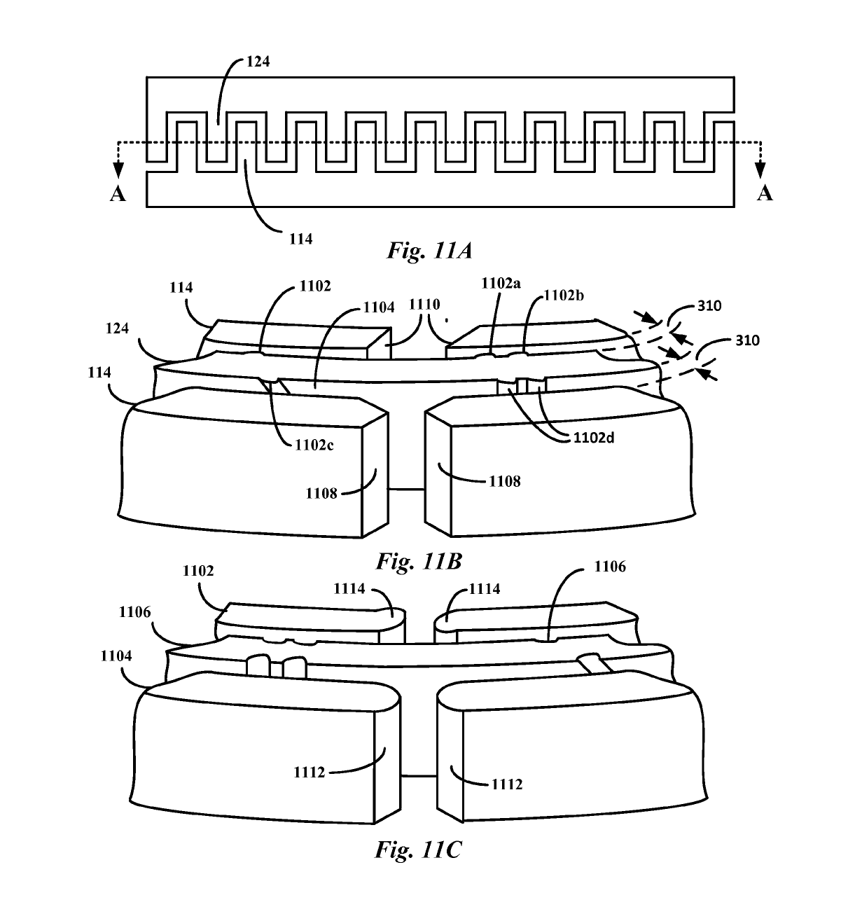

In other embodiments, the interdigitated fins 102 may include topographic structures to improve the heat transferring characteristics across the radial gaps δ 310. To that end, FIG. 11B schematically illustrates interdigitated fins 102 with features to improve the heat transferring characteristics of the radial gaps 310 according to an embodiment. The structures may, for example, disrupt the formation of undesired fully developed flow that would form due to the rotating structure's 116 rotation or form a localized secondary flow at the operating speed of the device to do the same. The figure shows a detailed cross-sectional view of a portion of the interdigitated fins 102 along a central plane A across FIG. 11A, including stationary fins 114 and rotating fin 124.

The rotating fins 124 include at least one protruding structure 1102 extending from the fin walls 1104. The protruding structure 1102 extends into the radial gaps 310 to generate a discontinuous fluid flow that disrupts undesired fully developed flows that may form due to the rotating fins 124 moving with respect to the stationary fins 114. Couette flow, for example, may form in the radial gaps 310 due to the shearing forces of the movement and the viscosity of the fluid. For a radial gaps 310 of around 50 microns, the protruding structure 1102 may extend into fifty percent of the width of the radial gaps δ (310). The protruding structure 1102 may be shaped as an arc (see FIG. 11B). Of course, other shapes may be employed, including rounded, squared, rectangular, and triangular shapes.

The rotating fins 124 may include multiple protruding structures 1102 on each side of the fin. The figure, for example, shows a set of protruding structures 1102 located in stages (e.g., a first stage 1102a and second stage 1102b). The protruding structures 1102 may be angled as shown with fin 1102c or vertical as shown with fins 1102d.

The protruding structure 1102 may be located on both sides of the rotating fin 124 to disrupt the formation of Couette flow in both neighboring radial gaps 310.

Alternatively, or in addition to, the protrusions 1102, the interdigitated fins 102 may include a recess 1106 to improve the heat transferring characteristics of the radial gaps 310.

FIG. 11C schematically illustrates interdigitated fins 102 with other features to improve the heat transferring characteristics of the radial gaps 310 according to another embodiment. The fins 114, 124 includes a recess 1106 to form a vortex as fluid flows along the wall 1104 of the rotating fin 124 flows into the recess 1106. The recess 1106 directs the flow in a direction generally perpendicular with fluid flow in the radial gaps 310. This flow merges with the fluid flowing along the wall 1104 at a confluent point to form the vortex that disrupts the formation of the Couette flow. The recess 1106 may be shaped as an arc (see FIG. 11C). Of course, other shapes may be employed, including rounded, squared, rectangular, and triangular shapes.

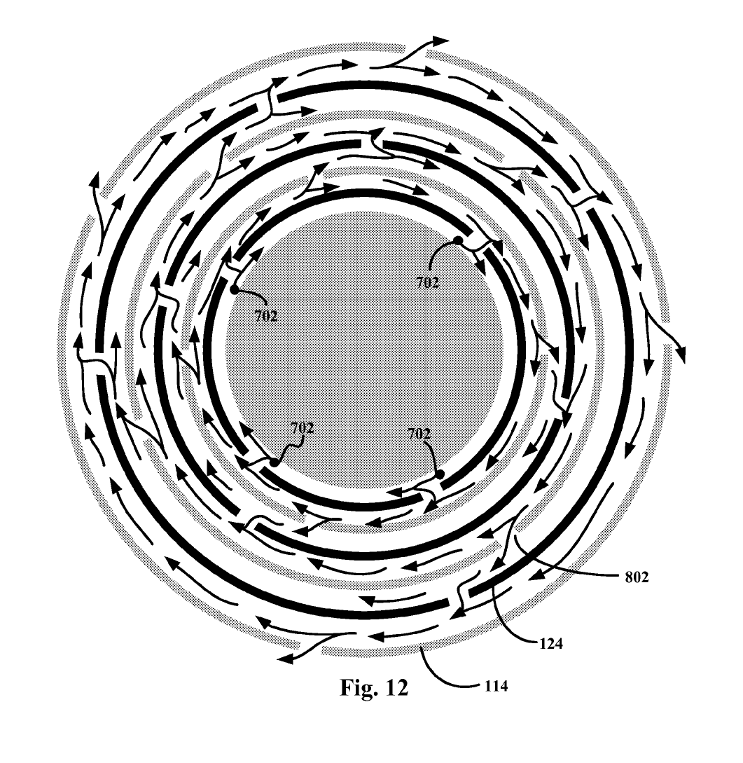

FIG. 12 illustratively show exemplary fluid flow within the interdigitated fins 102 according to an embodiment. Fluid enters radial gap 310a at circulation port 702 near the center of the device 100 and flows outwardly. Shearing forces of the movement of the rotating fin 124 causes the fluid to move within the radial gap 310. As discontinuity 802 of the rotating fin 124 passes the fluid, the flow diverges where a portion continues to flow along the radial gap 310 and another portion flows through the discontinuity 802. The divergence may disrupt the formation of undesired flow (e.g., Couette flow) from fully developing. Fluid also flows through the clearance h 406 between interdigitated fins 102. As fluid flows in the radial gaps 310, heat from the stationary fins 114 is transferred to the rotating fins 124.

The number of gaps and topographic features may be selected based on the rotating speed and the size of the radial gaps δ 310.

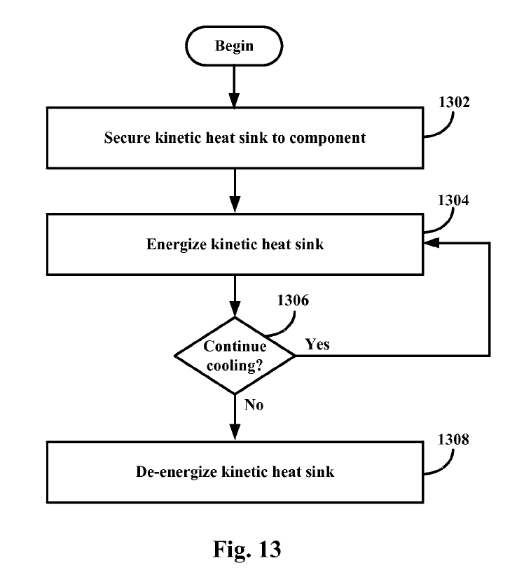

FIG. 13 shows a process of operating the kinetic heat sinks 100 in accordance with illustrative embodiments of the invention. In general, the process begins by securing the kinetic heat sink 100 to the heat-generating component 112 (step 1302), which may be, for example, a package of an electronic device or a printed circuit board. Various types of securing and mounting mechanisms known in the art may be used for these purposes. Among other things, those mechanisms may include screws, clips (e.g., z-clip, clip-on), push-pins, threaded standoffs, glue, thermal tapes, and thermal epoxies.

When at rest, the rotating structure 116 is seated, via the shaft 117, on the stationary portion 104 and retained by bearings 1002 (mechanical or hydrodynamic). The rotating structure 116 includes rotating fins 124 interdigitated with stationary fins 114 of the stationary portion to form a radial gap 310 (e.g., approximately 50 microns) between the fins 114, 124.

To begin cooling, the controller 1014 energizes the motor assembly 1008 (step 1304), causing the rotating portion of the motor 1008 to rotate along with the rotating structure 116. For example, the power may be derived from a DC voltage V_{AC} (e.g., 12V, 5V, etc.), an AC voltage, V_{AC}, or a pulse width modulated voltage. As the rotating structure 116 rotates, fluid in the radial gap 310 begins to move, as for example, shown in FIG. 12.

Topographical features on or of the rotating structure 116 or stationary portion 104 either disrupt the formation of undesired fully developed flow (e.g., Couette flow) or generate localized secondary flows to do the same. The topographical features thereby enhance the heat transfer characteristics of the radial gaps 310 allowing heat to more readily transfer from the stationary fins 114 to the rotating fins 124.

While rotating, the fluid-directing structure 120 (e.g., impeller) also rotates, causing the fluid in the channels between the fluid-directing structures 120 to move. As the fluid moves, heat from the fluid-directing structure 120 is rejected to the moving fluid and dispels into the thermal reservoir 304. Specifically, heat is drawn from the heat-generating component 112, spread across the base structure 106 to its stationary fins 114. Next, the heat transfers to the rotating fins 124 across the radial gaps 310, and then across the rotating base 118 to the fluid-directing structures 120.

At block 1306, the controller 1014 determines whether to continue to cool the heat-generating component 112. This may be based on a control signal or power being applied to the kinetic heat sink. Also, the controller 1014 may vary the rotation speed of the motor or the power output thereto based on temperature (e.g., at the heat-generating component 112 or various components of the kinetic heat sink) derived from the sensors 1016. If it is to continue cooling, then the process loops back to step 1304 to continue energizing the kinetic heat sink. When it is determined to no longer continuing cooling (e.g., the component being cooled is de-energized), then the process concludes at step 1308, in which the kinetic heat sink is de-energized. To that end, the controller 1014 may reduce power to the motor or remove power to the kinetic heat sink 100.

The embodiments of the invention described above are intended to be merely exemplary; numerous variations and modifications will be apparent to those skilled in the art. All such variations and modifications are intended to be within the scope of the present invention as defined in any appended claims. For example, protrusions and recesses may be located on the stationary fins to also disrupt formations of Couette flow.

What is claimed is:

1. A kinetic heat sink comprising:
a stationary portion having a first heat-conducting surface and a second heat-conducting surface to conduct heat therebetween, the stationary portion being mountable to a heat-generating component, the second heat-conducting surface having a first plurality of fins extending therefrom; and
a rotating structure rotatably coupled with the stationary portion, the rotating structure being configured to transfer heat received from the second heat-conducting surface to a thermal reservoir in thermal communication with the rotating structure,
the rotating structure having a movable heat-extraction surface with a second plurality of fins extending toward the first plurality of fins, at least a portion of the first plurality of fins being interdigitated with at least a portion of the second plurality of fins.

2. The kinetic heat sink of claim 1, wherein a portion of the first plurality of fins have a height to width ratio of at least two.

3. The kinetic heat sink of claim 1, wherein a portion of the second plurality of fins have a height to width ratio of at least two.

4. The kinetic heat sink of claim 1, wherein the a set of the first plurality of fins forms a radial gap with a set of the second plurality of fins, the radial gap being between about 25 microns and 200 microns.

5. The kinetic heat sink of claim 1, wherein the interdigitated fins are configured to have at least two times greater overlapping surface area in the radial direction than in the axial direction.

6. The kinetic heat sink of claim 1, wherein the stationary portion and rotating structure have facing surfaces that form an axial gap of at least 25 microns therebetween.

7. The kinetic heat sink of claim 1, wherein a portion of the first and second plurality of fins have a uniform cross-sectional area.

8. The kinetic heat sink of claim 1, wherein a portion of the first and second plurality of fins has a triangular cross-sectional area.

9. The kinetic heat sink of claim 1, wherein the first plurality of fins includes a first stationary fin having a first thickness and a second stationary fin having a second thickness, the first thickness being different from the second thickness.

10. The kinetic heat sink of claim 1, wherein the first plurality of fins includes a first stationary fin having a first height and a second stationary fin having a second height, the first height being different from the second height.

11. The kinetic heat sink of claim 1, wherein the second plurality of fins includes a first rotating fin having a first thickness and a second rotating fin having a second thickness, the first thickness being different from the second thickness.

12. The kinetic heat sink of claim 1, wherein the second plurality of fins includes a first rotating fin having a first height and a second rotating fin having a second height, the first height being different from the second height.

13. The kinetic heat sink of claim 1, wherein the radial gap includes a first radial gap at a first radial position and a second radial gap at a second radial position, the first radial gap being different than the second radial gap.

14. The kinetic heat sink of claim 1 wherein first plurality of fins are concentrically arranged.

15. The kinetic heat sink of claim 1 wherein the second plurality of fins are concentrically arranged.

16. The apparatus of claim 1, wherein the stationary portion and the rotating structure comprise a plurality of thermal conducting materials.

17. The apparatus of claim 1, wherein the stationary portion and the rotating structure comprise thermal conducting material including at least one of copper, aluminum, silver, nickel, iron, zinc, and combinations thereof.

18. The apparatus of claim 1, wherein the rotating structure rotatably moves with respect to the stationary portion at a rate sufficient for heat to readily transfer from the stationary portion to the rotating structure.

19. A method of dissipating heat from an electronic device, the method comprising:
providing a stationary structure having a first and second heat-conducting surface, the stationary structure being thermally coupled to the electronic device at the first heat-conducting surface to receive heat from the electronic device, the stationary structure conducting the received heat from the first heat-conducting surface to the second heat-conducting surface, wherein the second heat conducting surface comprises a first plurality of fins; and
rotating a rotating structure having a heat-extraction surface facing the second heat-conducting surface, the heat-extraction surface comprising a second plurality of fins interdigitated with the first plurality of fins, the act of rotating at least in part substantially transferring heat from the second heat-conducting surface to a thermal reservoir communicating with the rotating structure.

20. The method of claim 19 further comprising:
energizing an electric motor between the stationary structure and the rotating structure, the electric motor having (i) a stationary portion fixably attached to the stationary structure and (ii) a rotating portion fixably attached to the rotating structure, wherein the act of energizing causes the rotating structure to rotate.

21. The method of claim 20 wherein the stationary portion and rotational structure form a radial gap, the method further comprising:
generating discontinuous fluid flow in the radial gap between the second plurality of fins and the first plurality of fins, the discontinuous fluid flow urging fluid to flow within the radial gap.

22. The method of claim 19 wherein first plurality of fins and second plurality of fins are concentrically arranged.
